(19) United States
(12) Patent Application Publication
(10) Pub. No.: US 2025/0239816 A1
(43) Pub. Date: Jul. 24, 2025

(54) CONNECTOR ASSEMBLY WITH HEAT DISSIPATION PLATE

(71) Applicant: DONGGUAN LUXSHARE TECHNOLOGIES CO.,LTD, Dongguan City (CN)

(72) Inventors: Bin HUANG, Dongguan City (CN); Kunlin YAO, Dongguan City (CN); Qiongnan CHEN, Dongguan City (CN); Hongji CHEN, Dongguan City (CN)

(73) Assignee: DONGGUAN LUXSHARE TECHNOLOGIES CO.,LTD, Dongguan City (CN)

(21) Appl. No.: 18/749,832

(22) Filed: Jun. 21, 2024

(30) Foreign Application Priority Data
Jan. 18, 2024 (CN) 202410073017.3

(51) Int. Cl. H01R 13/6581; H01R 12/70

(52) U.S. Cl. CPC H01R 13/6581; H01R 12/7047

(57) ABSTRACT

A connector assembly includes a metal shielding cage and a heat dissipation plate. The metal shielding cage includes a first shell portion, a second shell portion and a receiving groove. The first shell portion includes a first receiving cavity configured to receive a first mating connector. The second shell portion includes a second receiving cavity configured to receive a second mating connector. The first shell portion and the second shell portion are configured to be mounted on a circuit board along a third direction. The third direction is perpendicular to the circuit board. The heat dissipation plate is inserted into the receiving groove along the third direction. The heat dissipation plate is configured to perform heat exchange with at least the first mating connector and the second mating connector.

### CROSS-REFERENCE TO RELATED APPLICATION

This patent application claims priority of a Chinese Patent Application No. 202410073017.3, filed on Jan. 18, 2024 and titled “CONNECTOR ASSEMBLY”, the entire content of which is incorporated herein by reference.

### TECHNICAL FIELD

The present disclosure relates to a connector assembly, which belongs to a technical field of connectors.

### BACKGROUND

A connector assembly in the related art generally includes an electrical connector for being mounted on a circuit board, and a metal shielding cage mounted on the circuit board and surrounding around the electrical connector. The electrical connector includes an insulating body and a plurality of conductive terminals. The insulating body defines a mating slot. Each conductive terminal includes an elastic contact portion protruding into the mating slot. The metal shielding cage defines a receiving space communicating with the mating slot. When the mating connector is inserted, the mating connector is received in the receiving space, a tongue plate of the mating connector is inserted into the mating slot, so that the conductive pads on the tongue plate contact corresponding elastic contact portions, thereby achieving electrical conduction.

However, as the signal transmission requirements of electrical connectors continue to increase, the density of the conductive terminals is also increasing, which also places higher requirements on heat dissipation.

### SUMMARY

An object of the present disclosure is to provide a connector assembly with improved heat dissipation effect.

In order to achieve the above object, the present disclosure adopts the following technical solution: a connector assembly, including: a metal shielding cage, the metal shielding cage including a first shell portion, a second shell portion and a receiving groove located between the first shell portion and the second shell portion along a first direction; the first shell portion including a first wall portion, a first side wall portion connected to the first wall portion, a second side wall portion connected to the first wall portion, and a first receiving cavity surrounded by at least the first wall portion, the first side wall portion and the second side wall portion; the first receiving cavity being configured to receive a first mating connector; the first side wall portion and the second side wall portion being spaced apart along a second direction; the second shell portion including a second wall portion, a third side wall portion connected to the second wall portion, a fourth side wall portion connected to the second wall portion, and a second receiving cavity surrounded by at least the second wall portion, the third side wall portion and the fourth side wall portion; the second receiving cavity being configured to receive a second mating connector; the third side wall portion and the fourth side wall portion being spaced apart along the second direction; the first receiving cavity including a first opening opened to the receiving groove; the second receiving cavity including a second opening opened to the receiving groove; the first opening and the second opening being disposed facing to each other; The first shell portion and the second shell portion being configured to be installed on a circuit board along a third direction; the third direction being perpendicular to the circuit board; each two of the first direction, the second direction and the third direction are perpendicular to each other; and a heat dissipation plate, the heat dissipation plate being inserted into the receiving groove along the third direction; the heat dissipation plate including a first side surface and a second side surface opposite to the first side surface; the first side surface being at least partially exposed to the first opening; the second side surface being at least partially exposed to the second opening; the heat dissipation plate being configured to perform heat exchange with at least the first mating connector and the second mating connector to dissipate heat from the first mating connector and the second mating connector.

Compared with the prior art, the metal shielding cage of the present disclosure is provided with the first receiving cavity, the second receiving cavity, and the receiving groove located between the first receiving cavity and the second receiving cavity. By arranging the heat dissipation plate inserted into the receiving groove along the third direction perpendicular to the circuit board, the heat dissipation plate can dissipate heat for the first mating connector inserted in the first receiving cavity and the second mating connector inserted in the second receiving cavity, thereby improving the heat dissipation effect. Besides, the heat generated on the circuit board can form a rising heat flow and be dissipated to a certain extent through the heat dissipation plate.

In order to achieve the above object, the present disclosure adopts the following technical solution: a connector assembly, including: a metal shielding cage, the metal shielding cage defining a receiving cavity configured to receive a mating connector along a third direction; the metal shielding cage being configured to be mounted on a circuit board along the third direction; the third direction being perpendicular to the circuit board; and a liquid cooling plate, the liquid cooling plate including a side surface at least partially exposed in the receiving cavity; the side surface being configured to at least contact a mating connector so as to dissipate heat from the mating connector via the liquid cooling plate.

Compared with the prior art, the metal shielding cage of the present disclosure is mounted on the circuit board along the third direction perpendicular to the circuit board. The liquid cooling plate can perform heat exchange with the mating connector, thereby improving the heat dissipation effect. Besides, the heat generated on the circuit board can form a rising heat flow and be dissipated to a certain extent through the liquid cooling plate.

### BRIEF DESCRIPTION OF DRAWINGS

FIG. 1 is a schematic perspective view of a connector assembly in accordance with an embodiment of the present disclosure;

FIG. 2 is a partially exploded perspective view of FIG. 1, in which a grounding sheet is separated;

FIG. 3 is a partial enlarged view of circled part B in FIG. 2;

FIG. 4 is a further perspective exploded view of FIG. 2, in which a plurality of grounding sheets and a plurality of support blocks are separated;

FIG. 5 is a partial enlarged view of circled part C in FIG. 4;

FIG. 6 is a perspective schematic view of a set of grounding sheets and one support block in FIG. 4;

FIG. 7 is a partially exploded perspective view of FIG. 4 from another angle;

FIG. 8 is a further exploded perspective view of FIG. 4;

FIG. 9 is a partial enlarged view of circled part D in FIG. 8;

FIG. 10 is a partial enlarged view of circled part E in FIG. 8;

FIG. 11 is a partially exploded perspective view of FIG. 8 from another angle;

FIG. 12 is a partial enlarged view of circled part F in FIG. 11;

FIG. 13 is an exploded perspective view of a plurality of metal shielding cages, a heat dissipation plate, a plurality of grounding sheets and a plurality of support blocks in accordance with an embodiment of the present disclosure;

FIG. 14 is an exploded perspective view of FIG. 13 from another angle;

FIG. 15 is a perspective view of a first connecting plate and a second connecting plate in FIG. 13; and

FIG. 16 is a schematic cross-sectional view taken along line G-G in FIG. 1.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

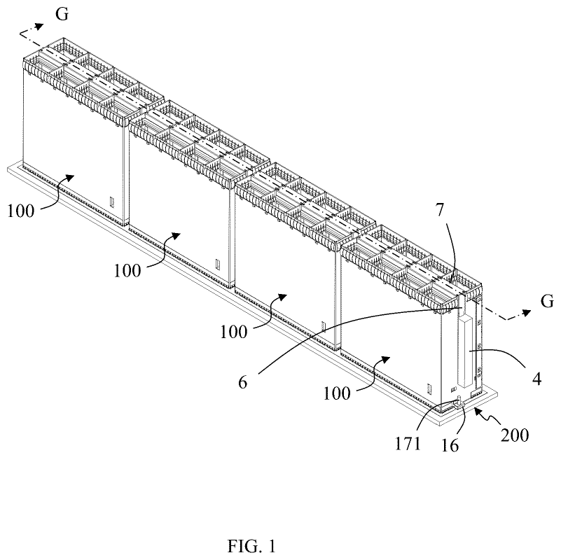

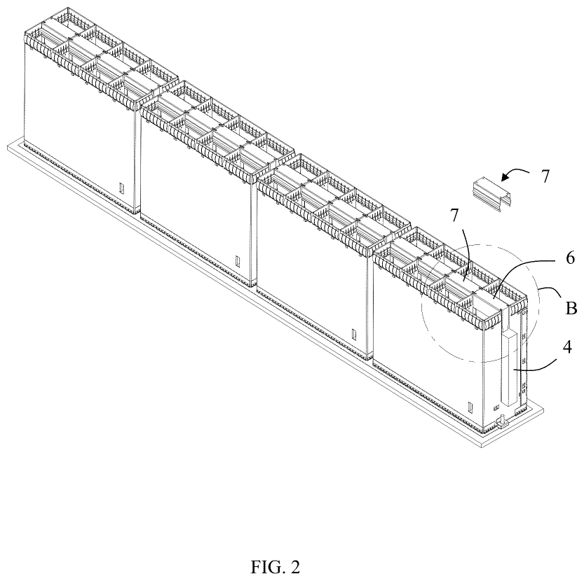

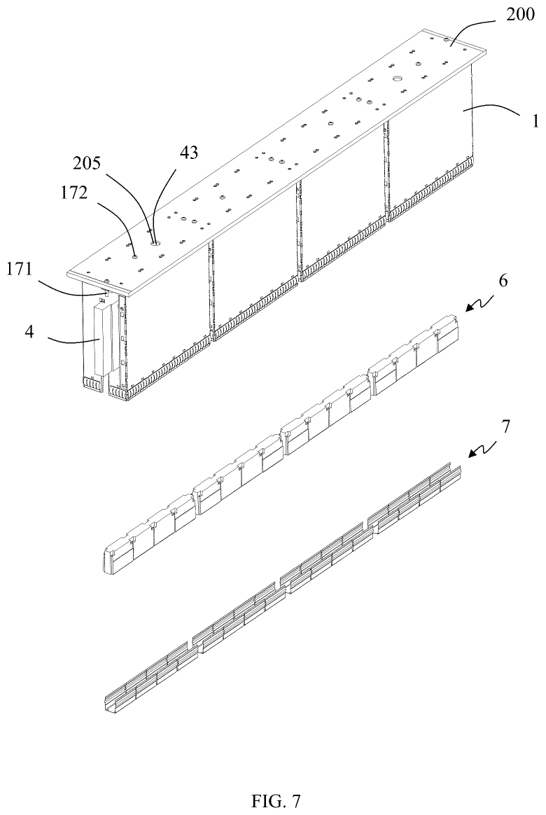

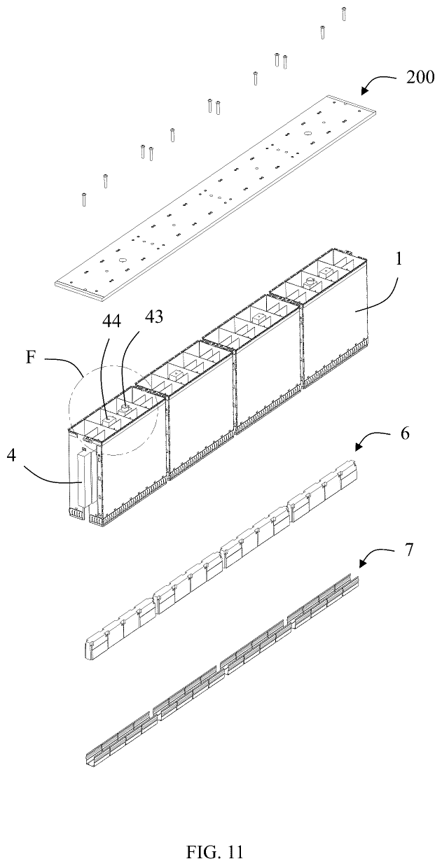

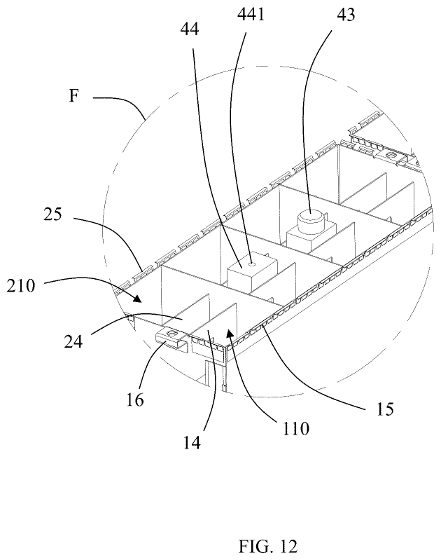

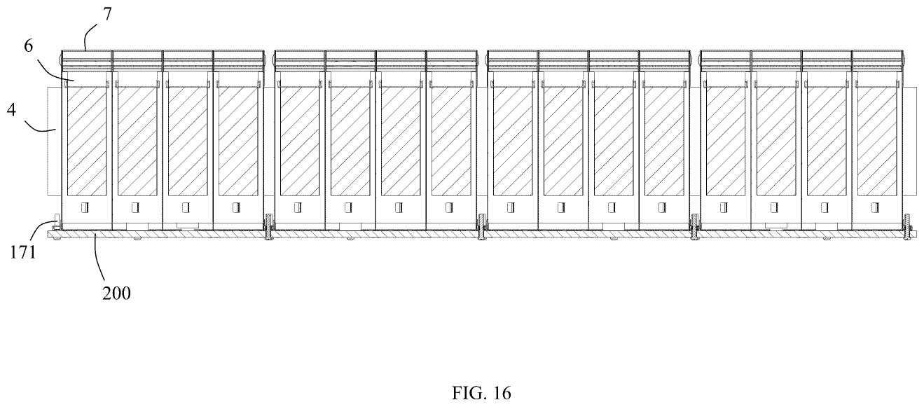

Referring to FIG. 1 to FIG. 16, the present disclosure discloses an assembly, which includes a circuit board 200 and a connector assembly 100 mounted on the circuit board 200.

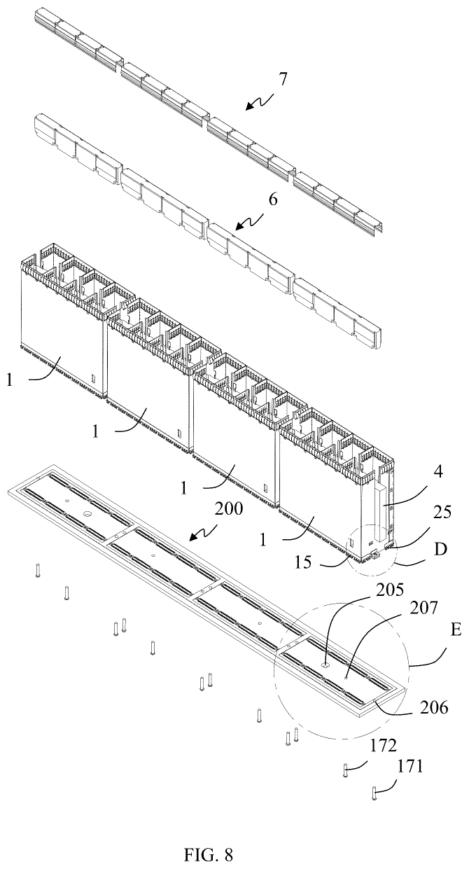

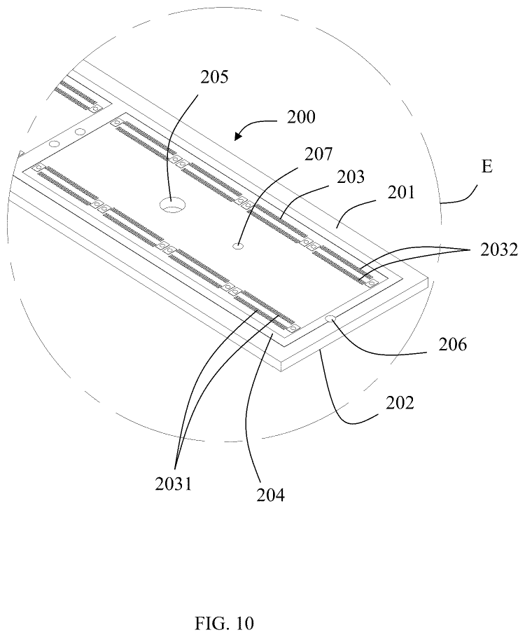

As shown in FIG. 8 and FIG. 10, the circuit board 200 includes a first surface 201 (for example, an upper surface), a second surface 202 (for example, a lower surface) opposite to the first surface 201, a plurality of conductive pads 203 exposed to the first surface 201, a grounding path 204 located around the plurality of conductive pads 203 and exposed to the first surface 201, a positioning hole 205 extending through the first surface 201 and the second surface 202, a first through hole 206 extending through the first surface 201 and the second surface 202, and a second through hole 207 extending through the first surface 201 and the second surface 202.

In the illustrated embodiment of the present disclosure, the circuit board 200 includes four mounting areas, and only one of the mounting areas will be described below as an example.

The plurality of conductive pads 203 located in the mounting area are divided into four groups. Each group of conductive pads 203 include a plurality of first conductive pads 2031 and a plurality of second conductive pads 2032. The plurality of first conductive pads 2031 are disposed in two rows. The plurality of second conductive pads 2032 are also disposed in two rows.

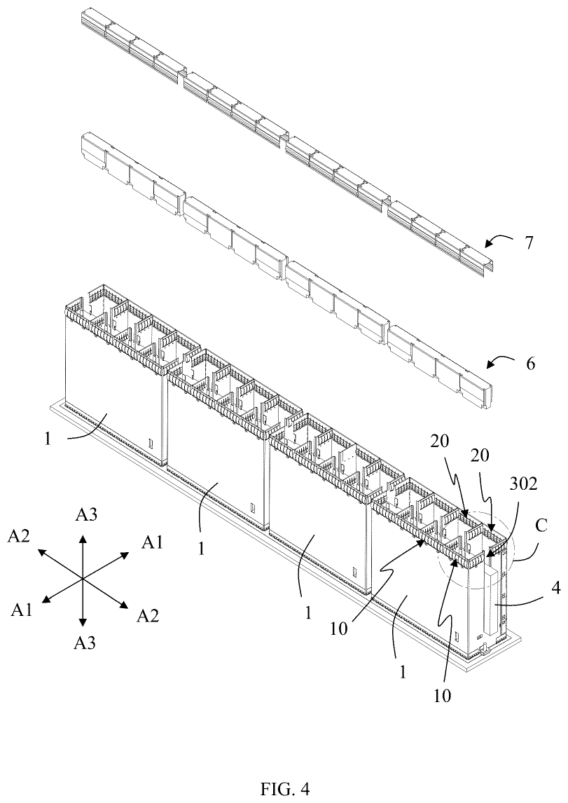

Referring to FIG. 4, in the illustrated embodiment of the present disclosure, the connector assembly 100 includes four metal shielding cages 1 and are mounted in four mounting areas of the circuit board 200, respectively. The structures of the four metal shielding cages 1 are similar, and only one of the metal shielding cages 1 will be described in detail below.

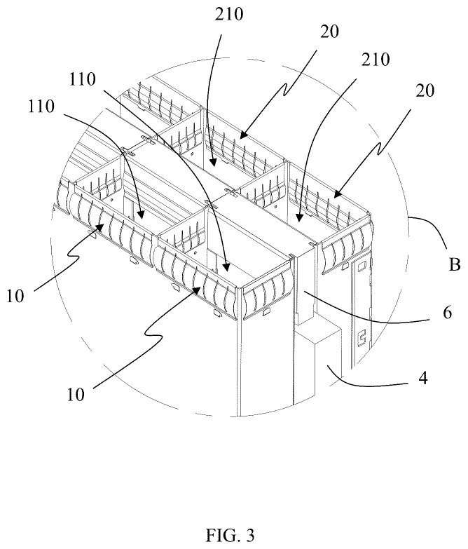

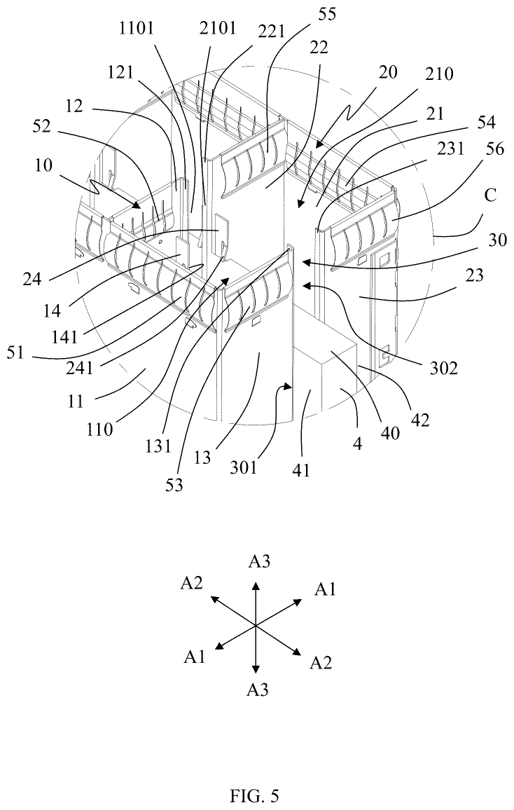

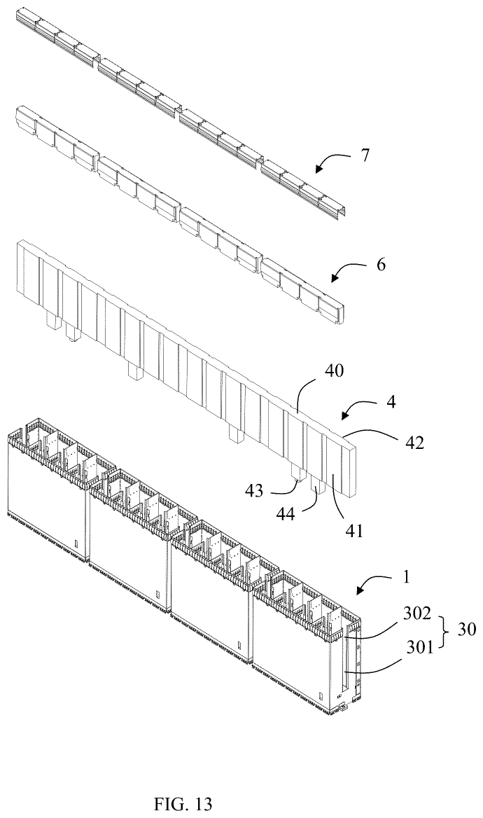

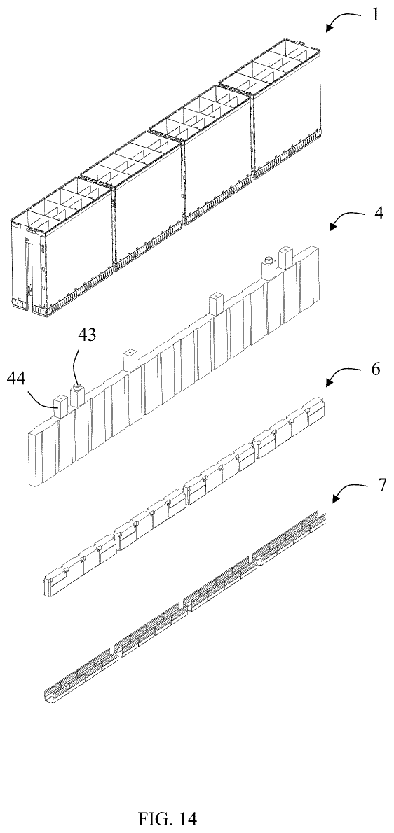

Referring to FIG. 3, FIG. 5, FIG. 13 and FIG. 14, the metal shielding cage 1 includes at least one first shell portion 10, at least one second shell portion 20, and a receiving groove located between the first shell portion 10 and the second shell portion 20 along a first direction A1-A1 (for example, a left-right direction). In the illustrated embodiment of the present disclosure, the receiving groove 30 includes a first receiving groove 301 and a second receiving groove 302 in communication with the first receiving groove 301. The first receiving groove 301 is located at a bottom of the second receiving groove 302.

The first shell portion 10 includes a first wall portion 11, a first side wall portion 12 connected to the first wall portion 11, a second side wall portion 13 connected to the first side wall portion 12, and a first receiving cavity 110 at least surrounded by the first wall portion 11, the first side wall portion 12 and the second side wall portion 13. The first receiving cavity 110 is configured to receive a first mating connector (for example, an OSFP plug connector, not shown). The first side wall portion 12 and the second side wall portion 13 are spaced apart along a second direction A2-A2 (for example, a front-rear direction). In the illustrated embodiment of the present disclosure, the first receiving cavity 110 is generally U-shaped. The first receiving cavity 110 has a first opening 1101 opened to the receiving groove 30.

Similarly, the second shell portion 20 includes a second wall portion 21, a third side wall portion 22 connected to the second wall portion 21, a fourth side wall portion 23 connected to the second wall portion 21, and a second receiving cavity 210 surrounded by at least the second wall portion 21, the third side wall portion 22 and the fourth side wall portion 23. The second receiving cavity 210 is configured to receive a second mating connector (for example, an OSFP plug connector, not shown). The third side wall portion 22 and the fourth side wall portion 23 are spaced apart along the second direction A2-A2. In the illustrated embodiment of the present disclosure, the second receiving cavity 210 is generally U-shaped. The second receiving cavity 210 has a second opening 2101 opened to the receiving groove 30. The first opening 1101 and the second opening 2101 are arranged opposite to each other. That is, the first opening 1101 is opened toward the second opening 2101, and the second opening 2101 is opened toward the first opening 1101.

Those skilled in the art can understand that the connector assembly 100 further includes a first receptacle connector (for example, an OSFP receptacle connector, not shown) mounted on the circuit board 200, and a second receptacle connector (for example, an OSFP receptacle connector, not shown) mounted on the circuit board 200.

The first receptacle connector includes a first insulating body and a plurality of first conductive terminals fixed in the first insulating body. The first insulating body defines a first mating slot extending upwardly through the first insulating body. The first mating slot upwardly communicates with the first receiving cavity 110. The first mating slot is configured to receive a first tongue plate of the first mating connector. The plurality of first conductive terminals protrude into the first mating slot in order to contact first gold fingers on the first tongue plate. The plurality of first conductive terminals are electrically connected (for example, welded or soldered) to the plurality of first conductive pads 2031. The first receptacle connector resides at a bottom of the first receiving cavity 110. The first shell portion 10 surrounds the first receptacle connector, but the first shell portion 10 is not fixed to the first insulating body. In other words, the first receptacle connector and the first shell portion 10 are respectively mounted on the circuit board 200, and the first shell portion 10 surrounds the first receptacle connector so as to achieve a better shielding effect.

The second receptacle connector includes a second insulating body and a plurality of second conductive terminals fixed in the second insulating body. The second insulating body defines a second mating slot extending upwardly through the second insulating body. The second mating slot upwardly communicates with the second receiving cavity 210. The second mating slot is configured to receive a second tongue plate of the second mating connector. The plurality of second conductive terminals protrude into the second mating slot in order to contact second gold fingers on the second tongue plate. The plurality of second conductive terminals are electrically connected (for example, welded or soldered) to the plurality of second conductive pads 2032. The second receptacle connector resides at a bottom of the second receiving cavity 210. The second shell portion 20 surrounds the second receptacle connector, but the second shell portion 20 is not fixed to the second insulating body. In other words, the second receptacle connector and the second shell portion 20 are respectively mounted on the circuit board 200, and the second shell portion 20 surrounds the first receptacle connector so as to achieve a better shielding effect.

The first shell portion 10 and the second shell portion 20 are configured to be mounted on the circuit board 200 along a third direction A3-A3 (for example, a top-bottom direction). The third direction A3-A3 is perpendicular to the circuit board 200. In the illustrated embodiment of the present disclosure, each two of the first direction A1-A1, the second direction A2-A2 and the third direction A3-A3 are perpendicular to each other.

Those skilled in the art can understand that in the illustrated embodiment of the present disclosure, a height of the metal shielding cage 1 along the third direction A3-A3 is greater than a width of the metal shielding cage 1 along the first direction A1-A1, and is also greater than a length of the metal shielding cage 1 along the second direction A2-A2.

In the illustrated embodiment of the present disclosure, a plurality of first housing portions 10 are provided and arranged along the second direction A2-A2; and a plurality of first receiving cavities 110 are provided and arranged at intervals along the second direction A2-A2. Similarly, a plurality of second shell portions 20 are provided and arranged along the second direction A2-A2; and a plurality of second receiving cavities 210 are provided and arranged at intervals along the second direction A2-A2. The plurality of the first receiving cavities 110 and the plurality of the second receiving cavities 210 are in communication with the receiving groove 30.

As shown in FIG. 5, in the illustrated embodiment of the present disclosure, the first shell portion 10 includes a first positioning tab 121 bent from the first side wall portion 12 and a second positioning tab 131 bent from the second side wall portion 13. The second shell portion 20 includes a third positioning tab 221 bent from the third side wall portion 22 and a fourth positioning tab 231 bent from the fourth side wall portion 23. Bending directions of the first positioning tab 121 and the second positioning tab 131 are the same or opposite. Bending directions of the third positioning tab 221 and the fourth positioning tab 231 are the same or opposite. In the illustrated embodiment of the present disclosure, the bending directions of the first positioning tab 121 and the second positioning tab 131 are opposite; and the bending directions of the third positioning tab 221 and the fourth positioning tab 231 are the same.

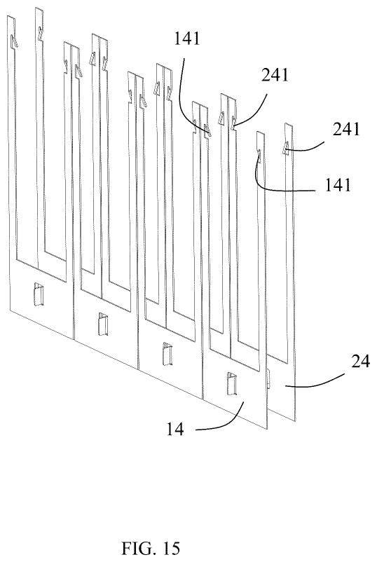

Referring to FIG. 5 and FIG. 15, in the illustrated embodiment of the present disclosure, the first shell portion 10 includes a first connecting plate 14 fixed to the first side wall portion 12 and the second side wall portion 13. The first connecting plate 14 is provided with a first abutting tab 141 that protrudes into the second receiving groove 302. In one embodiment of the present disclosure, the first abutting tab 141 is integrally stamped from the first connecting plate 14.

Similarly, the second shell portion 20 includes a second connecting plate 24 fixed to the third side wall portion 22 and the fourth side wall portion 23. The second connecting plate 24 is provided with a second abutting tab 241 protruding into the second receiving groove 302. In one embodiment of the present disclosure, the second abutting tab 241 is integrally stamped from the second connecting plate 24.

Referring to FIG. 5, the first shell portion 10 further includes a first elastic sheet 51 fixed to the first wall portion 11, a second elastic sheet 52 fixed to the first side wall portion 12, and a third elastic sheet 53 fixed to the second side wall portion 13. A part of the first elastic sheet 51 extends into the first receiving cavity 110, and another part of the first elastic sheet 51 is located outside the first receiving cavity 110; a part of the second elastic sheet 52 extends into the first receiving cavity 110, and another part of the second elastic sheet 52 is located outside the first receiving cavity 110; a part of the third elastic sheet 53 extends into the first receiving cavity 110, and another part of the third elastic sheet 53 is located outside the first receiving cavity 110. The first elastic sheet 51, the second elastic sheet 52 and the third elastic sheet 53, which extend into the first receiving cavity 110, are all configured to abut against the first mating connector to achieve grounding and provide holding force. Besides, the first elastic sheet 51, the second elastic sheet 52 and the third elastic sheet 53, which are located outside the first receiving cavity 110, are all configured to abut against a mounting plate (not shown) to achieve grounding.

The second shell portion 20 includes a fourth elastic sheet 54 fixed to the second wall portion 21, a fifth elastic sheet 55 fixed to the third side wall portion 22, and a sixth elastic sheet 56 fixed to the fourth side wall portion 23. A part of the fourth elastic sheet 54 extends into the second receiving cavity 210, and another part of the fourth elastic sheet 54 is located outside the second receiving cavity 210; a part of the fifth elastic sheet 55 extends into the second receiving cavity 210, and another part of the fifth elastic sheet 55 is located outside the second receiving cavity 210; a part of the sixth elastic sheet 56 extends into the second receiving cavity 210, and another part of the sixth elastic sheet 56 is located outside the second receiving cavity 210. The fourth elastic sheet 54, the fifth elastic sheet 55 and the sixth elastic sheet 56, which extend into the second receiving cavity 210, are all configured to abut against the second mating connector to achieve grounding and provide holding force. Besides, the fourth elastic sheet 54, the fifth elastic sheet 55 and the sixth elastic sheet 56, which are located outside the second receiving cavity 210, are all configured to abut against the mounting plate to achieve grounding.

In the illustrated embodiment of the present disclosure, the connector assembly 100 includes a heat dissipation plate 4, a plurality of support blocks 6 stacked on the heat dissipation plate 4, and a plurality of grounding sheets 7 installed on the plurality of support blocks 6.

The heat dissipation plate 4 is inserted into the first receiving groove 301 from top to bottom along the third direction A3-A3. The support block 6 is inserted into the second receiving groove 302 from top to bottom along the third direction A3-A3.

It is understandable to those skilled in the art that in the illustrated embodiment of the present disclosure, a height of the heat dissipation plate 4 along the third direction A3-A3 is greater than a width of the heat dissipation plate 4 along the first direction A1-A1, and is also greater than a length of the heat dissipation plate 4 along the second direction A2-A2.

During the insertion process of the heat dissipation plate 4, under the guidance of the first abutting tab 141 and the second abutting tab 241, the heat dissipation plate 4 first abuts against the first abutting tab 141 and the second abutting tab 241, so that the first abutting tab 141 and the second abutting tab 241 are deformed outwardly. When the heat dissipation plate 4 passes through the first abutting tab 141 and the second abutting tab 241, the heat dissipation plate 4 is completely located in the first receiving groove 301. At this time, the first abutting tab 141 and the second abutting tab 241 return to positions before deformation. A lower end surface of the first abutting tab 141 and a lower end surface of the second abutting tab 241 can upwardly limit a movement of the heat dissipation plate 4 in order to prevent the heat dissipation plate 4 from upwardly being separated from the first receiving groove 301.

In the illustrated embodiment of the present disclosure, a thickness of the support block 6 along the first direction A1-A1 is smaller than a thickness of the heat dissipation plate 4 along the first direction A1-A1. Therefore, when the support block 6 is inserted into the second receiving groove 302, the support block 6 does not abut against the first abutting tab 141 and the second abutting tab 241; or the support block 6 cannot abut against the first abutting tab 141 and the second abutting tab 241 outward to an extent that the heat dissipation plate 4 can move upwardly away from the first abutting tab 141 and the second abutting tab 241.

Referring to FIG. 5, FIG. 13 and FIG. 14, in the illustrated embodiment of the present disclosure, the heat dissipation plate 4 includes a top surface 40, a first side surface 41 and a second side surface 42 opposite to the first side surface 41. The first side surface 41 is at least partially exposed to the first opening 1101. The second side surface 42 is at least partially exposed to the second opening 2101. The heat dissipation plate 4 is configured to perform heat exchange with at least the first mating connector and the second mating connector to dissipate heat from the first mating connector and the second mating connector. In one embodiment of the present disclosure, the heat dissipation plate 4 is a liquid cooling plate, which includes a cooling liquid inlet (not shown), a cooling liquid outlet (not shown) and an internal flow channel (not shown) communicating with the cooling liquid inlet and the cooling liquid outlet. The cooling liquid inlet is configured to be filled with a liquid (for example, water). The liquid flows in the internal flow channel and exchanges heat with other components (such as the first mating connector and the second mating connector), and then flows out from the cooling liquid outlet.

Besides, the support block 6 defines a least one positioning groove. The first shell portion 10 and/or the second shell portion 20 includes at least one positioning tab that is fixed into the positioning groove along the third direction A3-A3.

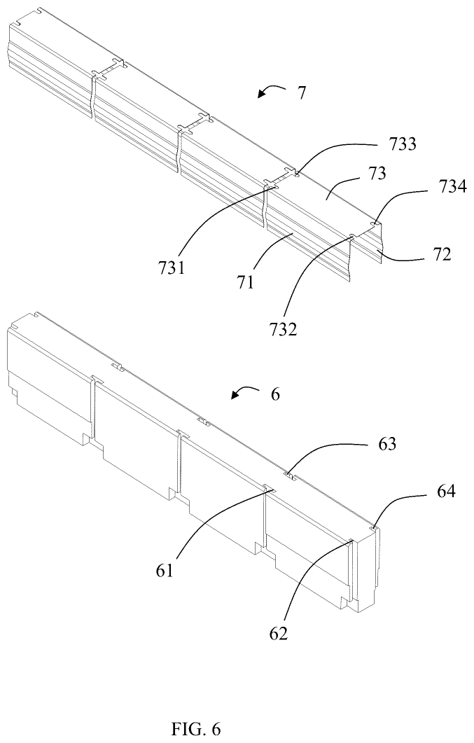

Referring to FIG. 6, in the illustrated embodiment of the present disclosure, the at least one positioning groove includes a first positioning groove 61, a second positioning groove 62, a third positioning groove 63 and a fourth positioning groove 64. The first positioning groove 61, the second positioning groove 62, the third positioning groove 63 and the fourth positioning groove 64 all extend through the support block 6 along the third direction A3-A3. The first positioning groove 61 and the second positioning groove 62 are located on one side of the support block 6 along the first direction A1-A1. The third positioning groove 63 and the fourth positioning groove 64 are located on another side of the support block 6 along the first direction A1-A1.

In the illustrated embodiment of the present disclosure, the at least one positioning tab includes the first positioning tab 121, the second positioning tab 131, the third positioning tab 221 and the fourth positioning tab 231. The first positioning tab 121 is fixed in the first positioning groove 61, the second positioning tab 131 is fixed in the second positioning groove 62, the third positioning tab 221 is fixed in the third positioning groove 63, and the fourth positioning tab 231 is fixed in the fourth positioning groove 64.

Referring to FIG. 5 and FIG. 6, each grounding sheet 7 includes a first abutting elastic arm 71 protruding into the first receiving cavity 110, a second abutting elastic arm 72 protruding into the second receiving cavity 210, and a connecting portion 73 connecting the first abutting elastic arm 71 and the second abutting elastic arm 72. The first abutting elastic arm 71 is configured to contact the first mating connector. The second abutting elastic arm 72 is configured to contact the second mating connector. The connecting portion 73 is in contact with a top surface of the support block 6.

Referring to FIG. 6, in the illustrated embodiment of the present disclosure, the connecting portion 73 defines a first slit 731 corresponding to the first positioning groove 61, a second slit 732 corresponding to the second positioning groove 62, a third slit 733 corresponding to the third positioning groove 63 and a fourth slit 734 corresponding to the fourth positioning groove 64. The first positioning tab 121 is received and fixed in the first positioning groove 61 and then further received and fixed in the first slit 731. The second positioning tab 131 is received and fixed in the second positioning groove 62 and then further received and fixed in the second slit 732. The third positioning tab 221 is received and fixed in the third positioning groove 63 and then further received and fixed in the third slit 733. The fourth positioning tab 231 is received and fixed in the fourth positioning groove 64 and then further received and fixed in the fourth slit 734.

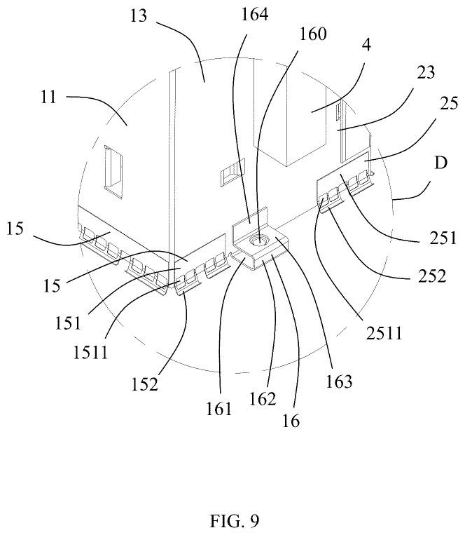

Referring to FIG. 8 and FIG. 9, in the illustrated embodiment of the present disclosure, the first shell portion 10 includes a plurality of first grounding elastic arms 15. The second shell portion 20 includes a plurality of second grounding elastic arms 25. The plurality of first grounding elastic arms 15 and the plurality of second grounding elastic arms 25 are configured to contact the grounding path 204 of the circuit board 200 so as to achieve grounding and shielding effects.

In the illustrated embodiment of the present disclosure, the plurality of first grounding elastic arms 15 are respectively fixed to a lower portion of the first wall portion 11, a lower portion of the first side wall portion 12 and a lower portion of the second side wall portion 13. The first grounding elastic arm 15 includes a first main body portion 151 that is fixed to the first wall portion 11, the first side wall portion 12 and the second side wall portion 13 by soldering or welding, and a first elastic contact portion 152 extending outward from the first main body portion 151. The first main body portion 151 defines a first through opening 1511. The first elastic contact portion 152 is arc-shaped and contacts the grounding path 204 of the circuit board 200 so as to achieve better grounding and shielding effects.

Similarly, in the illustrated embodiment of the present disclosure, the plurality of second grounding elastic arms 25 are respectively fixed to a lower portion of the second wall portion 21, a lower portion of the third side wall portion 22 and a lower portion of the fourth side wall portion 23. The second grounding elastic arm 25 includes a second main body portion 251 that is fixed to the second wall portion 21, the third side wall portion 22 and the fourth side wall portion 23 by soldering or welding, and a second elastic contact portion 252 extending outward from the second main body portion 251. The second main body portion 251 defines a second through opening 2511. The second elastic contact portion 252 is arc-shaped and contacts the grounding path 204 of the circuit board 200 so as to achieve better grounding and shielding effects.

It is understandable to those skilled in the art that in the illustrated embodiment of the present disclosure, the plurality of first grounding elastic arms 15 and the first shell portion are provided separately; the plurality of second grounding elastic arms 25 and the second shell portion 20 are provided separately. Of course, in other embodiments, the first grounding elastic arms 15 may also be integrally formed with the first wall portion 11, the first side wall portion 12 and the second side wall portion 13, respectively. The plurality of second grounding elastic arms 25 may also be integrally formed with the second wall portion 21, the third side wall portion 22 and the fourth side wall portion 23, respectively.

Referring to FIG. 9, in the illustrated embodiment of the present disclosure, the first shell portion 10 includes a first mounting tab 16 integrally bent from the second side wall portion 13. The first mounting tab 16 defines a first mounting hole 160 extending through the first mounting tab 16 along the third direction A3-A3. Specifically, the first mounting tab 16 includes a bottom plate 161 horizontally protruding outward from a bottom of the first side wall portion 12, a vertical plate 162 vertically bent upward from the bottom plate 161, a top plate 163 horizontally bent from a top of the vertical plate 162 toward the first side wall portion 12, and a fixing plate 164 vertically bent upwardly from the top plate 163. The first mounting hole 160 extends through the top plate 163 and the bottom plate 161 along the third direction A3-A3. The fixing plate 164 is attached to and fixed on the first side wall portion 12.

As shown in FIG. 8 and FIG. 9, the first through hole 206 of the circuit board 200 corresponds to the first mounting hole 160 along the third direction A3-A3. The connector assembly 100 includes a first fastener 171 (for example, a screw) that extends through the first through hole 206 and the first mounting hole 160, so as to secure the first mounting tab 16 to the circuit board 200.

In the illustrated embodiment of the present disclosure, a plurality of (for example, four) metal shielding cages 1 are provided and spaced apart along the second direction A2-A2. Each metal shielding cage 1 includes four first receiving cavities 110 and four second receiving cavities 210. Each metal shielding cage 1 is provided with one receiving groove 30. The heat dissipation plate 4 has an integral structure and is inserted into a plurality of receiving grooves of the plurality of the metal shielding cages 1.

In the illustrated embodiment of the disclosure, the first side wall portion 12 and the third side wall portion 22 are aligned along the first direction A1-A1; the second side wall portion 13 and the fourth side wall portion 23 are aligned along the first direction A1-A1. The four first receiving cavities 110 and the four second receiving cavities 210 of each metal shielding cage 1 are arranged in a 2*4 matrix.

Besides, as shown in FIG. 10 to FIG. 14, the heat dissipation plate 4 further includes a positioning post 43. The positioning post 43 is configured to be inserted into the positioning hole 205 of the circuit board 200. In addition, in order to improve the reliability of mounting the connector assembly 100 on the circuit board 200, the heat dissipation plate 4 further includes a plurality of mounting protrusions 44. Each mounting protrusion 44 defines a second mounting hole 441. The connector assembly 100 includes a second fastener 172 (for example, a screw) that passes through the second through hole 207 of the circuit board 200 and is screwed into the second mounting hole 441 so as to secure the mounting protrusion 44 to the circuit board 200.

In the present disclosure, the first fastener 171 and the second fastener 172 are provided, and the connector assembly 100 is installed and fixed on the circuit board 200. Even if the heights of the metal shielding cage 1 and the heat dissipation plate 4 along the third direction A3-A3 are greater than their respective lengths and widths, the metal shielding cage 1 and the heat dissipation plate 4 can still be reliably fixed, thereby preventing the metal shielding cage 1 and the heat dissipation plate 4 from being tilted due to external forces (for example, a pushing force in a horizontal plane).

Compared with the prior art, the metal shielding cage 1 of the present disclosure defines the first receiving cavity 110, the second receiving cavity 210, and the receiving groove located between the first receiving cavity 110 and the second receiving cavity 210. By arranging the heat dissipation plate 4 inserted into the receiving groove 30 along the third direction A3-A3 perpendicular to the circuit board 200, the heat dissipation plate 4 can dissipate heat for the first mating connector inserted into the first receiving cavity 110 and the second mating connector inserted into the second receiving cavity 210, thereby improving the heat dissipation effect. Besides, the heat generated on the circuit board 200 can form a rising heat flow and be dissipated to a certain extent via the heat dissipation plate 4.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A connector assembly, comprising:
a metal shielding cage, the metal shielding cage comprising a first shell portion, a second shell portion and a receiving groove located between the first shell portion and the second shell portion along a first direction; the first shell portion comprising a first wall portion, a first side wall portion connected to the first wall portion, a second side wall portion connected to the first wall portion, and a first receiving cavity surrounded by at least the first wall portion, the first side wall portion and the second side wall portion; the first receiving cavity being configured to receive a first mating connector; the first side wall portion and the second side wall portion being spaced apart along a second direction; the second shell portion comprising a second wall portion, a third side wall portion connected to the second wall portion, a fourth side wall portion connected to the second wall portion, and a second receiving cavity surrounded by at least the second wall portion, the third side wall portion and the fourth side wall portion; the second receiving cavity being configured to receive a second mating connector; the third side wall portion and the fourth side wall portion being spaced apart along the second direction; the first receiving cavity comprising a first opening opened to the receiving groove; the second receiving cavity comprising a second opening opened to the receiving groove; the first opening and the second opening being disposed facing to each other; The first shell portion and the second shell portion being configured to be installed on a circuit board along a third direction; the third direction being perpendicular to the circuit board; each two of the first direction, the second direction and the third direction are perpendicular to each other; and
a heat dissipation plate, the heat dissipation plate being inserted into the receiving groove along the third direction; the heat dissipation plate comprising a first side surface and a second side surface opposite to the first side surface; the first side surface being at least partially exposed to the first opening; the second side surface being at least partially exposed to the second opening; the heat dissipation plate being configured to perform heat exchange with at least the first mating connector and the second mating connector to dissipate heat from the first mating connector and the second mating connector.

2. The connector assembly according to claim 1, wherein the receiving groove comprises a first receiving groove and a second receiving groove in communication with the first receiving groove; the first receiving groove is located at a bottom of the second receiving groove; the heat dissipation plate is inserted into the first receiving groove; and
wherein the connector assembly further comprises a support block inserted into the second receiving groove and in contact with the heat dissipation plate.

3. The connector assembly according to claim 2, wherein the support block defines at least one positioning groove; the first shell portion and/or the second shell portion comprises at least one positioning tab that is fixed in the at least one positioning groove along the third direction.

4. The connector assembly according to claim 3, wherein the at least one positioning groove comprises a first positioning groove, a second positioning groove, a third positioning groove and a fourth positioning groove; the first positioning groove, the second positioning groove, the third positioning groove and the fourth positioning groove all extend through the support block along the third direction; the first positioning groove and the second positioning groove are located on one side of the support block along the first direction; the third positioning groove and the fourth positioning groove are located on another side of the support block along the first direction;
the first shell portion comprises a first positioning tab bent from the first side wall portion and a second positioning tab bent from the second side wall portion; the second shell portion comprises a third positioning tab bent from the third side wall portion and a fourth positioning tab bent from the fourth side wall portion; bending directions of the first positioning tab and the second positioning tab are the same or opposite; bending directions of the third positioning tab and the fourth positioning tab are the same or opposite;
the at least one positioning tab comprises the first positioning tab, the second positioning tab, the third positioning tab and the fourth positioning tab; the first positioning tab is fixed in the first positioning groove; the second positioning tab is fixed in the second positioning groove; the third positioning tab is fixed in the third positioning groove; and the fourth positioning tab is fixed in the fourth positioning groove.

5. The connector assembly according to claim 2, further comprising a grounding sheet mounted on the support block; the grounding sheet comprising a first abutting elastic arm extending into the first receiving cavity and a second abutting elastic arm extending into the second receiving cavity; the first abutting elastic arm being configured to abut against the first mating connector; the second abutting elastic arm being configured to abut against the second mating connector.

6. The connector assembly according to claim 2, wherein the first shell portion comprises a first connecting plate fixed to the first side wall portion and the second side wall portion; the first connecting plate is provided with a first abutting tab protruding into the second receiving groove;
the second shell portion comprises a second connecting plate fixed to the third side wall portion and the fourth side wall portion; the second connecting plate is provided with a second abutting tab protruding into the second receiving groove;
the first abutting tab and the second abutting tab are configured to restrict the heat dissipation plate so as to prevent the heat dissipation plate from being separated from the first receiving groove.

7. The connector assembly according to claim 1, wherein the first shell portion comprises a plurality of first grounding elastic arms; The second shell portion comprises a plurality of second grounding elastic arms; the plurality of first grounding elastic arms and the plurality of second grounding elastic arms are configured to be in contact with a grounding path of the circuit board.

8. The connector assembly according to claim 1, wherein the first side wall portion and the third side wall portion are aligned along the first direction; the second side wall portion and the fourth side wall portion are aligned along the first direction;
the first shell portion comprises a first elastic sheet fixed to the first wall portion, a second elastic sheet fixed to the first side wall portion, and a third elastic sheet fixed to the second side wall portion; a part of the first elastic sheet extends into the first receiving cavity, and another part of the first elastic sheet is located outside the first receiving cavity; a part of the second elastic sheet extends into the first receiving cavity, and another part of the second elastic sheet is located outside the first receiving cavity; a part of the third elastic sheet extends into the first receiving cavity, and another part of the third elastic sheet is located outside the first receiving cavity; the first elastic sheet, the second elastic sheet and the third elastic sheet, which extend into the first receiving cavity, are configured to abut against the first mating connector;
the second shell portion comprises a fourth elastic sheet fixed to the second wall portion, a fifth elastic sheet fixed to the third side wall portion, and a sixth elastic sheet fixed to the fourth side wall portion; a part of the fourth elastic sheet extends into the second receiving cavity, and another part of the fourth elastic sheet is located outside the second receiving cavity; a part of the fifth elastic sheet extends into the second receiving cavity, and another part of the fifth elastic sheet is located outside the second receiving cavity; a part of the sixth elastic sheet extends into the second receiving cavity, and another part of the sixth elastic sheet is located outside the second receiving cavity; the fourth elastic sheet, the fifth elastic sheet and the sixth elastic sheet, which extend into the second receiving cavity, are configured to abut against the second mating connector.

9. The connector assembly according to claim 1, wherein the first shell portion comprises a first mounting tab integrally bent from the second side wall portion; the first mounting tab defines a first mounting hole extending through the first mounting tab along the third direction;
the circuit board defines a first through hole corresponding to the first mounting hole along the third direction;
the connector assembly comprises a first fastener extending through the first through hole and the first mounting hole, so as to fix the first mounting tab on the circuit board.

10. The connector assembly according to claim 1, wherein the heat dissipation plate is a liquid cooling plate which comprises a cooling liquid inlet, a cooling liquid outlet, and an internal flow channel communicating with the cooling liquid inlet and the cooling liquid outlet.

11. The connector assembly according to claim 1, wherein a plurality of first shell portions are provided and arranged along the second direction; a plurality of first receiving cavities are provided and arranged at intervals along the second direction;
a plurality of second shell portions are provided and arranged along the second direction; a plurality of second receiving cavities are provided and arranged at intervals along the second direction;
the plurality of the first receiving cavities and the plurality of the second receiving cavities are in communication with the receiving groove.

12. The connector assembly according to claim 11, wherein a plurality of metal shielding cages are provided and disposed arranged at intervals along the second direction; each metal shielding cage defines the receiving groove;
the heat dissipation plate has an integral structure and is inserted into a plurality of the receiving grooves of the plurality of the metal shielding cages.

13. The connector assembly according to claim 1, wherein the heat dissipation plate comprises a positioning post, the circuit board defines a positioning hole to receive the positioning post.

14. The connector assembly according to claim 1, wherein the heat dissipation plate comprises a mounting protrusion defining a second mounting hole;
the circuit board defines a second through hole corresponding to the second mounting hole along the third direction;
the connector assembly comprises a second fastener extending through the second through hole and screwed into the second mounting hole so as to secure the mounting protrusion to the circuit board.

15. A connector assembly, comprising:
a metal shielding cage, the metal shielding cage defining a receiving cavity configured to receive a mating connector along a third direction; the metal shielding cage being configured to be mounted on a circuit board along the third direction; the third direction being perpendicular to the circuit board; and
a liquid cooling plate, the liquid cooling plate comprising a side surface at least partially exposed in the receiving cavity; the side surface being configured to at least contact a mating connector so as to dissipate heat from the mating connector via the liquid cooling plate.

16. The connector assembly according to claim 15, wherein the metal shielding cage comprises a first shell portion, a second shell portion, and a receiving groove located between the first shell portion and the second shell portion along a first direction; the first shell portion and the second shell portion are configured to be mounted on the circuit board along the third direction; the first shell portion defines a first receiving cavity configured to receive a first mating connector; the second shell portion defines a second receiving cavity configured to receive a second mating connector;
the receiving cavity comprises the first receiving cavity and the second receiving cavity;
the liquid cooling plate is inserted into the receiving groove along the third direction; the side surface comprises a first side surface at least partially exposed in the first receiving cavity and a second side surface at least partially exposed in the second receiving cavity; the first side surface is configured to contact the first mating connector so as to dissipate heat from the first mating connector; the second side surface is configured to contact the second mating connector so as to dissipate heat from the second mating connector.

17. The connector assembly according to claim 15, wherein the receiving groove comprises a first receiving groove and a second receiving groove communicating with the first receiving groove; the first receiving groove is located at a bottom of the second receiving groove; the liquid cooling plate is inserted into the first receiving groove;
the connector assembly further comprises a support block inserted into the second receiving groove and in contact with the liquid cooling plate.

18. The connector assembly according to claim 17, further comprising a grounding sheet mounted on the support block; the grounding sheet comprising an abutting elastic arm protruding into the receiving cavity; the abutting elastic arm being configured to abut against the mating connector.

19. The connector assembly according to claim 15, wherein the liquid cooling plate comprises a positioning post; the circuit board defines a positioning hole to receive the positioning post.

20. The connector assembly according to claim 15, wherein the liquid cooling plate comprises a mounting protrusion defining a second mounting hole;
the circuit board defines a second through hole corresponding to the second mounting hole along the third direction;
the connector assembly comprises a second fastener extending through the second through hole and screwed into the second mounting hole so as to secure the mounting protrusion to the circuit board.
